(19) United States
(12) Patent Application Publication
(10) Pub. No.: US 2026/0020439 A1
(43) Pub. Date: Jan. 15, 2026

(54) DISPLAY PANEL, DISPLAY APPARATUS AND MANUFACTURING METHOD FOR DISPLAY PANEL

(71) Applicants: HEFEI BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(72) Inventor: Wenbin Jia, Beijing (CN)

(73) Assignees: HEFEI BOE JOINT TECHNOLOGY CO., LTD., Hefei, Anhui (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/992,818

(22) PCT Filed: May 29, 2024
(86) PCT No.: PCT/CN2024/096142

§ 371 Date: Jan. 9, 2025

(30) Foreign Application Priority Data
Jun. 13, 2023 (CN) 202310701514.9

(51) Int. Cl. H10K 59/122; H10K 59/12; H10K 102/00

(52) U.S. Cl. CPC H10K 59/122; H10K 59/1201; H10K 2102/351

(57) ABSTRACT

A display panel, a display apparatus and a method for manufacturing the display panel, which is related to the technical field of display. Including a back plate, wherein a planarization layer is arranged on the back plate; and the planarization layer is provided with a pixel defining layer setting area, and the pixel defining layer setting area includes a lyophilic area and a lyophobic area, wherein the lyophilic area and the lyophobic area are criss-cross arranged; the planarization layer is provided with a groove at a position where the lyophilic area is located; the groove is provided with a lyophilic pixel defining layer; and the lyophobic area is provided with a lyophobic pixel defining layer.

### CROSS-REFERENCE TO RELATED APPLICATION

The present disclosure claims the priority of Chinese patent application with application number of 202310701514.9 filed in the CNIPA on Jun. 13, 2023 and entitled “DISPLAY PANEL, DISPLAY APPARATUS AND MANUFACTURING METHOD FOR DISPLAY PANEL”, the entire contents of which are incorporated herein by reference.

### FIELD

The present disclosure relate to the technical field of display in general, and in particular relates to a display panel, a display apparatus and a manufacturing method for the display panel.

### BACKGROUND

A film forming method of organic light emitting diode (OLED) mainly include evaporation process and solution process. At present, evaporation technology has been applied to mass production, but the material of this technology is expensive and the utilization rate of materials is low, which increases the cost of product development. The film forming methods of OLED in solution process mainly include inkjet printing, nozzle coating, spin coating, screen printing and so on.

### SUMMARY

A display panel, a display apparatus and a method for manufacturing the display panel are provided.

In a first aspect, provided a display panel, including a back plate, wherein a planarization layer is arranged on the back plate; and

the planarization layer is provided with a pixel defining layer setting area, and the pixel defining layer setting area includes a lyophilic area and a lyophobic area, wherein the lyophilic area and the lyophobic area are criss-cross arranged; the planarization layer is provided with a groove at a position where the lyophilic area is located; the groove is provided with a lyophilic pixel defining layer; and the lyophobic area is provided with a lyophobic pixel defining layer.

In an embodiment, an orthographic projection of the groove on the back plate is not less than an orthographic projection of the lyophilic pixel defining layer on the back plate.

In an embodiment, the lyophilic pixel defining layer is arranged higher than the planarization layer.

In an embodiment, a height of the lyophilic pixel defining layer above the planarization layer is H1, wherein, 0.6 μm≥H1≥0.3 μm.

In an embodiment, the lyophobic pixel defining layer forms a channel for ink to circulate.

In an embodiment, a thickness of the lyophilic pixel defining layer is H2, wherein, 3 μm≥H2≥2 μm.

In an embodiment, pixel electrodes are arranged between adjacent lyophilic areas and adjacent lyophobic areas.

In an embodiment, a thickness of the lyophobic pixel defining layer is H3, wherein, 1.5 μm≥H3≥1 μm.

In an embodiment, a depth of the groove of the planarization layer is H2-H1.

In an embodiment, the lyophobic pixel defining layer includes a plurality of first parts arranged along a first direction and at least two second parts arranged along a second direction, and a through area is arranged between adjacent first parts, and the through area is configured to accommodate ink drops, wherein the first direction and the second direction are not parallel.

In an embodiment, the lyophilic pixel defining layer is arranged in the through area.

In an embodiment, the lyophilic pixel defining layer extends along the second direction.

In an embodiment, a height of the lyophobic pixel defining layer is higher than that of the lyophilic pixel defining layer.

In an embodiment, the first direction and the second direction are not perpendicular.

In an embodiment, the back plane includes a substrate and a driving circuit structure arranged on the substrate.

As a second aspect, provided a display apparatus, including the display panel mentioned above.

As a third aspect, provided a method for manufacturing the display panel as mentioned above, including steps of: providing the back plane;

opening the groove at the position of the lyophilic area on the planarization layer; and

arranging the lyophilic pixel defining layer in the groove, and arranging the lyophobic pixel defining layer in the lyophobic area.

In an embodiment, the lyophilic pixel defining layer is arranged beyond an upper surface of the planarization layer.

In an embodiment, after a step of arranging the lyophilic pixel defining layer in the groove and arranging the lyophilic pixel defining layer beyond the upper surface of the planarization layer, and arranging the lyophobic pixel defining layer in the lyophobic area, the method further includes:

arranging pixel electrodes between the adjacent lyophilic areas and the adjacent lyophobic areas.

In an embodiment, after a step of arranging pixel electrodes between the adjacent lyophilic areas and the adjacent lyophobic areas, the method further includes:

arranging print ink and/or other parts of the display panel between the adjacent lyophilic areas and the adjacent lyophobic areas.

The above description is only an overview of the technical solution of the present disclosure, which can be implemented according to the contents of the specification in order to understand the technical means of the present disclosure more clearly, and in order to make the above and other purposes, features and advantages of the present disclosure more obvious and understandable, the following is specific embodiments of the present disclosure.

### BRIEF DESCRIPTION OF THE DRAWINGS

In order to more clearly explain the technical solution in the embodiments of the present disclosure or related art, the drawings needed to be used in the description of the embodiments or related art will be briefly introduced below. Apparently, the drawings in the following description are some embodiments of the present disclosure, and other drawings can be obtained according to these drawings without expenditure of creative labor for persons skilled in the art.

Other features, objects and advantages of the present disclosure will become more apparent by reading the detailed description of non-limiting embodiments with reference to the following drawings:

FIG. 1 is a schematic cross-sectional view of a back plate and a planarization layer in an embodiment of the present disclosure;

FIG. 2 is a schematic cross-sectional view of a display panel in an embodiment of the present disclosure;

FIG. 3 is a top view of FIG. 2; and

FIG. 4 is a flowchart of a manufacturing method for a display panel according to an embodiment of the present disclosure.

### DETAILED DESCRIPTION

In order to make the purpose, technical solution and advantages of the embodiments of the present disclosure clearer, the technical solution in the embodiments of the present disclosure will be described clearly and completely with the appended drawings. Apparently, the described embodiments are a part of the embodiments of the present disclosure, but not the whole embodiment. Based on the embodiments in the present disclosure, all other embodiments obtained by persons skilled in the art without expenditure of creative labor belong to the protection scope of the present disclosure.

The present disclosure will be further described in detail with the appended drawings and examples. It can be understood that the specific embodiments described here are only used to explain the related invention, but not to limit the present disclosure. In addition, for the convenience of description, only the parts related to the present disclosure are shown in the drawings.

It should be noted that the embodiments in the present disclosure and the features in the embodiments can be combined with each other without conflict. The present disclosure will be described in detail with reference to the appended drawings and examples.

In the inkjet printing process, a pixel defining layer (PDL) needs to be made on an electrode of a substrate in advance, to limit the ink droplets to accurately flow into a designated R/G/B sub-pixel area. For the traditional pixel structure, a uniformity of film formation in a pixel decreases with an increase of a resolution (255 ppi) and a decrease of a pixel opening, thus affecting the life and quality of the product. In addition, due to a limitation of printer nozzle hardware, a stability of each nozzle can't guarantee a consistency of a volume in each pixel. Although the mixed algorithm is used for printing, a Suji Mura (a kind of uneven display caused by the inconsistency of inkjet volumes between nozzles) can't be avoided. Finally, the higher the printing accuracy is required for high-resolution products, the higher the requirements for short-side and long-side directions of pixels. Therefore, it is necessary to develop a new pixel structure, a Line Bank, in which the ink of each column of the same color sub-pixels is circulated mutually, so that the ink of each sub-pixel is averaged, the ink volume difference of sub-pixels is reduced, and at the same time, due to an influence of atmosphere, the uniformity of printing film is improved. Moreover, the Line Bank reduces hardware accuracy requirements of printers. At present, there are two kinds of Line Banks commonly used in the industry, a double-layer Line Bank and a single-layer Line Bank (Half Tone), and the single-layer Line Bank is generally not considered at present due to material limitations.

At present, in the verification of Line Bank technology, it is found that the thickness of the lyophilic pixel defining layer is relative thin (0.4-06 μm) in the process, which is helpful for ink circulation. However, due to the characteristics of lyophilic materials, the target thickness cannot be coated at one time. At present, the main process thickness is relatively stable at 2.2 μm, and it needs to be Half Tone, which leads to the uniformity getting worse and the non-uniformity is getting more and more with the decrease of the thickness of the pixel defining layer, and the main reason is that the Half Tone requires the light stability of the exposure machine and the exposure window is small.

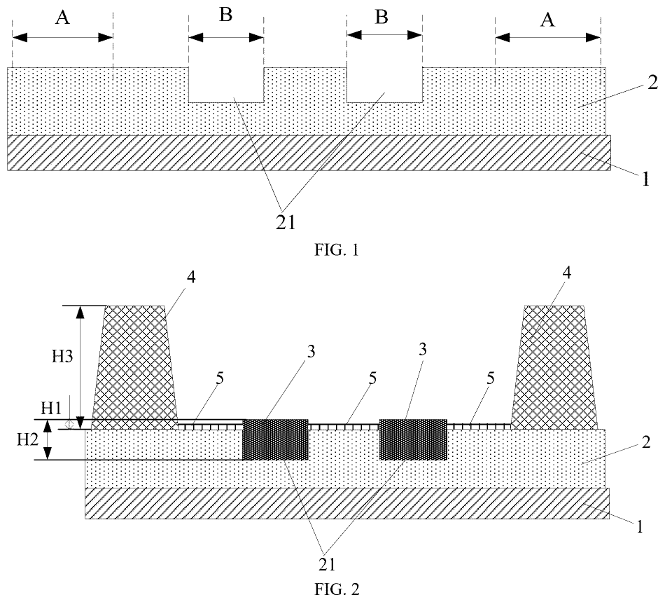

Referring to FIG. 1 to FIG. 3, this embodiment provides a display panel, which includes a back plate 1, and a planarization layer 2 is provided on the back plate 1.

The planarization layer 2 is provided with a pixel defining layer setting area, which includes a lyophilic area B and a lyophobic area A, wherein the lyophilic area B and the lyophobic area A are criss-cross arranged: the planarization layer 2 is provided with a groove 21 at a position where the lyophilic area B is located, and a lyophilic pixel defining layer 3 is arranged in the groove 21, and the lyophobic area A is provided with a lyophobic pixel defining layer 4.

In the display panel provided by this embodiment, the pixel defining layer is arranged on the planarization layer 2, and the position of the lyophilic area B of the pixel defining layer is provided with a groove 21 structure, and the lyophilic pixel defining layer is arranged in the groove 21, so that a process window of the lyophilic pixel defining layer 3 is greatly increased, a uniformity of a film thickness of the corresponding lyophilic pixel defining layer 3 is improved, a fluidity of the pixel ink in the same column of the formed pixel defining layer is improved, a display unevenness is reduced, thereby reducing a risk of overflow and color crosstalk, and improving a display quality.

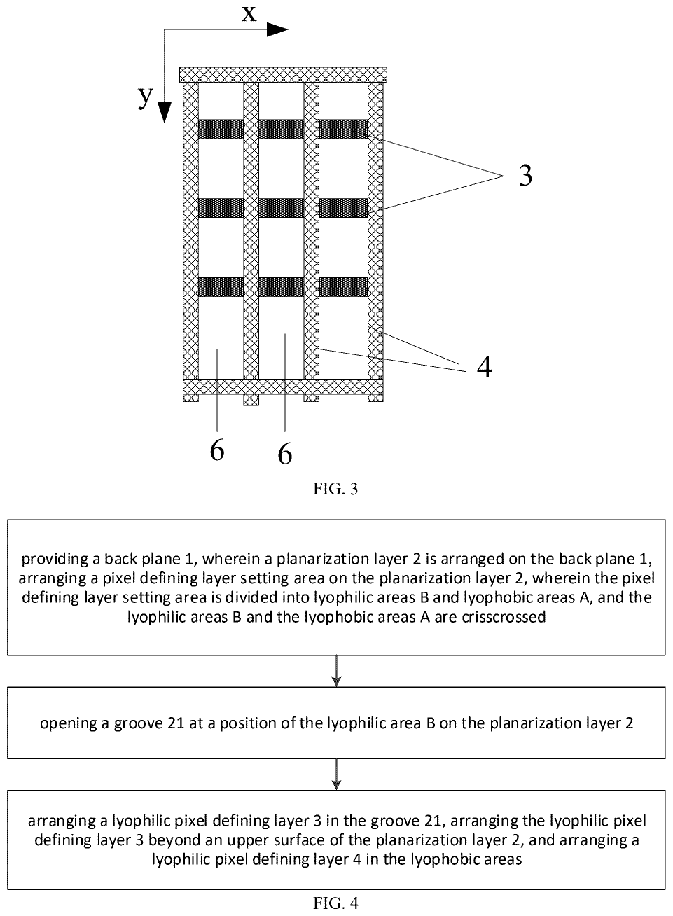

As shown in FIG. 3, the pixel defining layer on the display panel is formed by criss-crossing lyophilic materials and lyophobic materials, and the lyophobic materials are set higher, and ink flow channels are formed in columns between adjacent lyophobic materials. Dropping ink in the ink flow channels can make the ink of each sub-pixel average, reduce a volume difference of the ink of sub-pixels and improve the uniformity of printing film. Wherein, the pixel defining layer is formed by lyophilic material and lyophobic material, the lyophilic material forms the lyophilic pixel defining layer 3 as shown in FIG. 3, and the lyophobic material forms the lyophobic pixel defining layer 4 as shown in FIG. 3. The thickness of pixel defining layers with different thicknesses, especially the thickness of the lyophilic pixel defining layer 3, determines whether the printing ink can flow smoothly and whether the thickness of the formed inkjet printing layer is relatively uniform. Generally, the thickness of the lyophilic pixel defining layer 3 is set to be relatively thin, which is helpful for ink circulation. However, when the thickness of the lyophilic pixel defining layer 3 is about 2.2 microns in the current process, the process is relatively stable, and the thickness of the formed lyophilic pixel defining layer 3 is uniform, correspondingly, the ink circulation is smoother, and the thickness of the formed inkjet printing layer is also uniform. Therefore, the setting of thickness of the pixel defining layer needs to meet requirements of facilitating ink circulation and easy manufacturing.

As shown in FIG. 2, the lyophilic pixel defining layer 3 is not only arranged above the planarization layer 2, but also arranged in the groove 21 opened on the planarization layer 2. The thickness of the lyophilic pixel defining layer 3 is increased by the arranged groove 21, but the thickness of the lyophilic pixel defining layer 3 beyond the planarization layer 2 can still meet a standard of thinner, which can facilitate the circulation of ink.

Further, the orthogonal projection of the groove 21 on the back plate 1 is not less than the set orthogonal projection of the lyophilic pixel defining layer 3 on the back plate 1.

The lyophilic pixel defining layer 3 need to be arranged on the display panel provided by this embodiment, which has a structure with certain width and length. In this embodiment, a groove 21 for accommodating the lyophilic pixel defining layer 3 is provided on the planarization layer 2, and the groove 21 needs to be slightly larger than the set width and length of the lyophilic pixel defining layer 3, at least covering a set size of the structure, so that the lyophilic pixel defining layer 3 formed in the groove 21 can meet a requirement of size.

Further, the lyophilic pixel defining layer 3 is set higher than the planarization layer 2 by a height H1, wherein, 0.6 μm ≥H1≥0.3 μm.

In this embodiment, the lyophilic pixel defining layer 3 needs to be set beyond the planarization layer 2 by a certain height, and the lyophilic pixel defining layer 3 beyond the height needs to be set to be relatively thin, with a thickness conducive to ink circulation, and the lyophilic pixel defining thickness can be optionally set to be between 0.6 micron and 0.3 micron. Since the lyophilic pixel defining layer 3 is partially arranged in the groove 21, The overall thickness can be set to be relatively thick, so that the thickness beyond the planarization layer 2 can be set to a desired thickness at any time. The lyophilic pixel defining layer 3 contributes to the circulation of ink, thereby, the formed inkjet printing layer has uniform thickness, the display panel is uniform and the display quality is stable.

Further, the thickness of the lyophilic pixel defining layer 3 is H2, wherein, 3 μm≥H2≥2 μm.

As shown in FIG. 1, the lyophilic pixel defining layer 3 provided by this embodiment is arranged in the groove 21 on the planarization layer 2, and the thickness of the lyophilic pixel defining layer 3 is increased by the groove 21, so that the thickness of the structure may be set in a range of stable process. The thickness of the lyophilic pixel defining layer 3 may be optionally set to 2-3 microns, and may be optionally set to 2.2 microns. The thickness in the process is relatively stable, and the thickness of the lyophilic pixel defining layer 3 is relatively stable. The requirement that thickness of the lyophilic pixel defining layer 3 is beyond the planarization layer 2 can be satisfied without other processes, so that the manufacturing of the structure can be carried out under a stable process, and at the same time, the effect of facilitating ink circulation that can only be satisfied with a thinner thickness can be satisfied. According to the thickness of the lyophilic pixel defining layer 3 and the thickness of the pixel defining layer beyond the planarization layer 2, the depth of the groove 21 of the planarization layer 2 is H2-H1, generally 2.4 μm-1.7 μm.

Optionally, pixel electrodes 5 are arrange between adjacent lyophilic areas B and adjacent lyophobic areas A.

As shown in FIG. 2, the pixel electrodes 5 are arranged between adjacent lyophilic areas B and lyophobic areas A, and the pixel electrodes 5 are arranged at intervals between the criss-crossing lyophilic areas B and lyophobic areas A as shown in FIG. 3.

Optionally, the thickness of the lyophobic pixel defining layer 4 is H3, wherein, 1.5 μm≥H3≥1 μm.

In the display panel provided by this embodiment, a channel for ink to circulate is formed by the lyophobic pixel defining layer 4, and the thickness of the lyophobic pixel defining layer 4 is optionally set to be between 1 micron and 1.5 microns.

Further, the lyophobic pixel defining layer 4 includes a plurality of first parts arranged along a first direction and at least two second parts arranged along a second direction, and a through area 6 is arranged between adjacent first parts, and the through area 6 is used to accommodate ink drops.

As shown in FIG. 3, the lyophobic pixel defining layers 4 include parts extending along a y-axis direction, and there are lyophilic pixel defining layers 3 between adjacent lyophobic pixel defining layers 4. The lyophilic pixel defining layers 3 are arranged extending along a x-axis direction. The height of the lyophobic pixel defining layers 4 is higher than that of the lyophobic pixel defining layers 3, and a through area is formed between the lyophobic pixel defining layers 4 to accommodate ink. The corresponding lyophobic pixel defining layers 4 are also arranged at outermost sides of the lyophilic pixel defining layers 3, which may intercept the printing ink. Further, the lyophilic pixel defining layer 3 is arranged in the through area 6.

In this embodiment, the lyophilic pixel defining layer 3 in the through area 6 is retained, and the effective thickness of the lyophilic pixel defining layer 3, that is, the thickness exceeding that of the planarization layer 2, is set relatively small to facilitate the circulation of ink. This embodiment also provides a display apparatus, including the display panel.

In the specific implementation process, the display apparatus provided by this embodiment may be any product or component with display function, such as a mobile phone, a tablet computer, a television, a display, a notebook computer, a digital photo frame, a navigator, etc. Other essential components of the display apparatus should be understood by those skilled in the art, and are not repeated here, nor should they be used as limitations to the present disclosure. As shown in FIG. 4, this embodiment also provides a method for manufacturing the display panel, which includes the following steps:

providing a back plane 1, wherein a planarization layer 2 is arranged on the back plane 1;

arranging a pixel defining layer setting area on the planarization layer 2, wherein the pixel defining layer setting area is divided into lyophilic areas B and lyophobic areas A, and the lyophilic areas B and the lyophobic areas A are crisscrossed;

opening a groove 21 at a position of the lyophilic area B on the planarization layer 2;

arranging the lyophilic pixel defining layer 3 in the groove 21, arranging a lyophilic pixel defining layer 3 beyond an upper surface of the planarization layer 2, and arranging a lyophilic pixel defining layer 4 in the lyophobic areas.

When manufacturing the display panel provided by the above embodiments, firstly, a back plane 1 is provided, which includes a substrate and a driving circuit structure arranged on the substrate, a planarization layer 2 is arranged on the back plane 1, and then grooves 21 are arranged on the planarization layer 2 to form the structure shown in FIG. 1, wherein the grooves 21 on the planarization layer 2 are specifically arranged at the position where the lyophilic area B is located, and the depth of the grooves 21 can be selectively set between 2.4 μm and 1.7 μm according to the above embodiment. The lyophobic areas A on the planarization layer 2 are not performed other settings.

Subsequently, a pixel defining layer is arranged on the planarization layer 2, and specifically, the lyophilic pixel defining layer 3 is arranged in the groove 21 and exceeds the planarization layer 2 by a certain distance. A thickness of the lyophilic pixel defining layer 3 beyond the planarization layer 2 can be optionally set to be 0.6 μm≥H1≥0.3 μm, which can be understood as an effective thickness of the lyophilic pixel defining layer 3. This thickness can ensure that the ink for subsequent ink-jet printing has good fluidity between the lyophobic pixel defining layers 4. In fact, the set thickness of the pixel defining layers themselves are relatively thick, which can be manufactured with stable thickness in the existing process. At the same time, the lyophobic pixel defining layers 4 are set in the lyophobic area A with a setting thickness of 1-1.5 μm, and a through area 6 is formed between adjacent lyophobic pixel defining layers 4 to accommodate ink.

Subsequently, pixel electrodes 5 are arranged at intervals between the pixel defining layers, forming the structure shown in FIG. 2.

Subsequently, the printing ink and other structures are set in the intervals between the pixel defining layers.

It should be understood that the orientation or position relationships indicated above involving the terms “center”, “vertical”, “horizontal”, “up”, “down”, “front”, “back”, “left”, “right”, “vertical”, “horizontal”. “top”, “bottom”, “inside”, “outside”, etc., are based on the orientation or position relationships shown in the attached drawings. Only for the purpose of facilitating the description and simplifying the description of the present disclosure, but not to indicate or imply that the device or element referred to must have a particular orientation, construction and operation in a particular orientation, and therefore shall not be construed as a limitation of the present disclosure; The term “inside and outside” refers to the inside and outside relative to the outline of each part itself. In addition, the terms “first” and “second” are used for descriptive purposes only and are not to be understood as indicating or implying relative importance or as implicitly indicating the quantity of technical features indicated. Thus, a feature defined as “first” or “second” may explicitly or implicitly include one or more such features.

For ease of description, spatial relative terms can be used here, such as “on top of”, “above”, “on upper surface”, “above”, etc., is used to describe the spatial position relationship between one device or feature and other devices or features as shown in the figure. It should be understood that spatial relative terms are intended to include different orientations in use or operation other than those described in the diagram of the device. For example, if a device in the appended drawings is inverted, a device described as “above” or “upper” another device or structure will later be positioned as “below” or “under” another device or structure. Thus, the exemplary term “above” can include “above” and “below” two directions. The device can also be positioned rotated 90 degrees or in other directions in different ways, and the relative description of space used here is explained accordingly.

The above description is only a better embodiment of the present disclosure and an

explanation of the technical principles used. Persons skilled in the art shall understand that the scope of invention referred to in the present disclosure shall not be limited to technical solutions resulting from particular combinations of such technical features, but shall also cover other technical solutions resulting from any combination of such technical features or their equivalents without leaving the idea of the invention. For example, the technical solution formed by replacing the above features with the technical features disclosed in the present disclosure (but not limited to) having similar functions.

The device embodiments described above are schematic only, where the units described as separate components may or may not be physically separate, and the components shown as units may or may not be physical units, that is, may be located in one place, or may be distributed over multiple network units. Some or all of the modules can be selected according to the actual needs to realize the purpose of this embodiment. It can be understood and implemented by those skilled in the art without expenditure of creative labor.

References herein to “one embodiment”, “embodiment” or “one or more embodiments”

mean that a particular feature, structure or characteristic described in combination with an embodiment is included in at least one embodiment of the present disclosure. In addition, please note that the examples of words “in an embodiment” here do not all refer to the same embodiment.

A great deal of detail is given in the specification provided here. However, it is understood that embodiments of the present disclosure may be practiced without these specific details. In some instances, publicly known methods, structures and techniques are not shown in detail so as not to obscure the understanding of this specification.

In claims, any reference symbol located between parentheses should not be constructed as a limitation of the claim. The word “includes” does not exclude the existence of elements or steps not listed in the claim. The word “one” or “a” before a component does not rule out the existence of more than one such component. The present disclosure may be implemented by means of hardware comprising a number of different elements and by means of a properly programmed computer. In a unit claim that lists several devices, several of these devices may be embodied by the same hardware item. The use of the words first, second, and third does not indicate any order. These words can be interpreted as names.

Finally, it should be noted that the above embodiments are used only to illustrate the technical proposal of the present disclosure, and not to restrict it; Notwithstanding the detailed description of the present disclosure by reference to the foregoing embodiments, it should be understood by persons skilled in the art that they may modify the technical solution recorded in the foregoing embodiments, or make equivalent substitutions for some of the technical features;

Such modification or replacement shall not remove the essence of the respective technical proposals from the spirit and scope of the respective embodiments of the present disclosure.

1. A display panel, comprising a back plate, wherein a planarization layer is arranged on the back plate; and
the planarization layer is provided with a pixel defining layer setting area, and the pixel defining layer setting area comprises a lyophilic area and a lyophobic area, wherein the lyophilic area and the lyophobic area are criss-cross arranged; the planarization layer is provided with a groove at a position where the lyophilic area is located; the groove is provided with a lyophilic pixel defining layer; and the lyophobic area is provided with a lyophobic pixel defining layer.

2. The display panel according to claim 1, wherein an orthographic projection of the groove on the back plate is not less than an orthographic projection of the lyophilic pixel defining layer on the back plate.

3. The display panel according to claim 1, wherein the lyophilic pixel defining layer is arranged higher than the planarization layer.

4. The display panel according to claim 3, wherein a height of the lyophilic pixel defining layer above the planarization layer is H1, wherein, 0.6 μm≥H1≥0.3 μm.

5. The display panel according to claim 1, wherein the lyophobic pixel defining layer forms a channel for ink to circulate.

6. The display panel according to claim 3, wherein a thickness of the lyophilic pixel defining layer is H2, wherein, 3 μm≥H2≥2 μm.

7. The display panel according to claim 1, wherein pixel electrodes are arranged between adjacent lyophilic areas and adjacent lyophobic areas.

8. The display panel according to claim 1, wherein a thickness of the lyophobic pixel defining layer is H3, wherein, 1.5 μm≥H3≥1 μm.

9. The display panel according to claim 6, wherein a depth of the groove of the planarization layer is H2-H1.

10. The display panel according to claim 1, wherein the lyophobic pixel defining layer comprises a plurality of first parts arranged along a first direction and at least two second parts arranged along a second direction, and a through area is arranged between adjacent first parts, and the through area is configured to accommodate ink drops, wherein the first direction and the second direction are not parallel.

11. The display panel according to claim 10, wherein the lyophilic pixel defining layer is arranged in the through area.

12. The display panel according to claim 11, wherein the lyophilic pixel defining layer extends along the second direction.

13. The display panel according to claim 11, wherein a height of the lyophobic pixel defining layer is higher than that of the lyophilic pixel defining layer.

14. The display panel according to claim 10, wherein the first direction and the second direction are not perpendicular.

15. The display panel according to claim 1, wherein the back plane comprises a substrate and a driving circuit structure arranged on the substrate.

16. A display apparatus comprising the display panel according to claim 1.

17. A manufacturing method of a display panel according to claim 1, comprising steps of:
providing the back plane;
opening the groove at the position of the lyophilic area on the planarization layer; and
arranging the lyophilic pixel defining layer in the groove, and arranging the lyophobic pixel defining layer in the lyophobic area.

18. The manufacturing method according to claim 17, wherein the lyophilic pixel defining layer is arranged beyond an upper surface of the planarization layer.

19. The manufacturing method according to claim 17, wherein after a step of arranging the lyophilic pixel defining layer in the groove and arranging the lyophilic pixel defining layer beyond the upper surface of the planarization layer, and arranging the lyophobic pixel defining layer in the lyophobic area, the method further comprises:
arranging pixel electrodes between the adjacent lyophilic areas and the adjacent lyophobic areas.

20. The manufacturing method according to claim 19, wherein after a step of arranging pixel electrodes between the adjacent lyophilic areas and the adjacent lyophobic areas, the method further comprises:
arranging print ink and/or other parts of the display panel between the adjacent lyophilic areas and the adjacent lyophobic areas.
